(19) United States
(12) Patent Application Publication
(10) Pub. No.: US 2012/0013343 A1
(43) Pub. Date: Jan. 19, 2012

(54) RECEIVING APPARATUS, TEST APPARATUS, RECEIVING METHOD, AND TEST METHOD

(75) Inventor: Nobuei WASHIZU, Saitama (JP)

(73) Assignee: ADVANTEST CORPORATION, Tokyo (JP)

(21) Appl. No.: 13/209,428

(22) Filed: Aug. 14, 2011

Related U.S. Application Data
(63) Continuation of application No. PCT/JP2009/002294, filed on May 25, 2009.

(51) Int. Cl. G01R 31/02; H03L 7/06

(52) U.S. Cl. 324/537; 327/156

(57) ABSTRACT

A receiving apparatus that acquires a reception signal using a recovered clock that is recovered from an edge of the reception signal. The receiving apparatus comprises a recovered clock generating section that generates the recovered clock; a multi-strobe generating section that generates a plurality of strobes having different phases from each other, according to a pulse of the recovered clock; a detecting section that detects an edge position of the reception signal relative to the strobes, based on a value of the reception signal at timings of each of the strobes; an adjusting section that adjusts a phase of the recovered clock according to the edge position of the reception signal; and an acquiring section that acquires the reception signal at a timing shifted by a set phase difference, which is set in advance, from the recovered clock.

### BACKGROUND

1. Technical Field

The present invention relates to a receiving apparatus, a test apparatus, a receiving method, and a test method.

2. Related Art

A device is known that outputs a data signal in parallel with a clock signal that indicates an acquisition timing of the data signal, such as a DDR-SDRAM. A test apparatus for testing such a device uses a multi-strobe function. A device is also known that outputs a signal resulting from a clock component being superimposed on a data signal, such as a device adopting the serial ATA IF standard.
Japanese Patent Application Publication No. 2003-315428
Japanese Patent Application Publication No. 2004-127455

When testing a device that outputs the data signal and the clock signal in parallel, the test apparatus is preferably adjusted prior to testing in order to generate the multi-strobe at the correct timing.

A test apparatus that tests a device outputting a signal obtained by superimposing the clock component on the data signal must recover the clock from the data signal output from the device and acquire the clock according to the strobe signal. However, when the multi-strobe function of the test apparatus is used with this type of device, it is difficult to recover the clock from the data signal using the multi-strobe function.

Furthermore, even if the clock recovered from the output signal of the device is adjusted, it is still necessary to adjust the data strobe signal, which is generated within the test apparatus, according to the recovered clock, and a phase difference occurs between the recovered clock and the strobe signal.

### SUMMARY

Therefore, it is an object of an aspect of the innovations herein to provide a receiving apparatus, a test apparatus, a receiving method, and a test method, which are capable of overcoming the above drawbacks accompanying the related art. The above and other objects can be achieved by combinations described in the independent claims. The dependent claims define further advantageous and exemplary combinations of the innovations herein. According to a first aspect related to the innovations herein, provided is a receiving apparatus that acquires a reception signal using a recovered clock that is recovered from an edge of the reception signal. The receiving apparatus comprises a recovered clock generating section that generates the recovered clock; a multi-strobe generating section that generates a plurality of strobes having different phases from each other, according to a pulse of the recovered clock; a detecting section that detects an edge position of the reception signal relative to the strobes, based on a value of the reception signal at timings of each of the strobes; an adjusting section that adjusts a phase of the recovered clock according to the edge position of the reception signal; and an acquiring section that acquires the reception signal at a timing shifted by a set phase difference, which is set in advance, from the recovered clock.

The summary clause does not necessarily describe all necessary features of the embodiments of the present invention. The present invention may also be a sub-combination of the features described above.

### BRIEF DESCRIPTION OF THE DRAWINGS

FIG. 1 shows an exemplary configuration of a test apparatus 10 according to an embodiment of the present invention, along with a device under test 300.

FIG. 2 shows an exemplary configuration within the receiving apparatus 20 according to the present embodiment.

FIG. 3 shows an exemplary process performed by the adjusting section 34 and acquisition timing of the acquiring section 36 according to the present embodiment.

FIG. 4 shows a process flow of the receiving apparatus 20 according to the present embodiment.

FIG. 5 shows a configuration of the receiving apparatus 20 according to a modification of the present embodiment.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

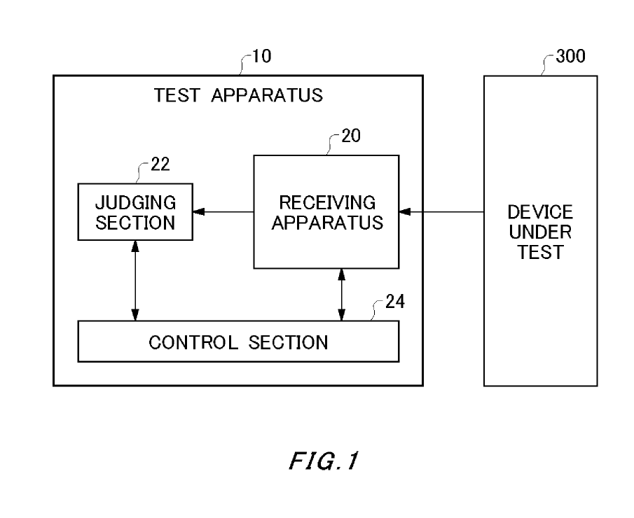

FIG. 1 shows an exemplary configuration of a test apparatus 10 according to an embodiment of the present invention, along with a device under test 300. The test apparatus 10 tests the device under test 300. The device under test 300 may be a device such as a DDR-SDRAM (Double-Data-Rate Synchronous Dynamic Random Access Memory) that outputs a data signal in parallel with a clock signal that indicates an acquisition timing at which the data signal is acquired.

Instead, the device under test 300 may transmit, as a single clock-embedded signal, the data signal and a reference timing for acquiring the data signal. In this case, the test apparatus 10 branches the single clock-embedded signal into two signals. The test apparatus 10 then receives one of these branched signals as the data signal and receives the other as the clock signal. As another example, the device under test 300 may transmit two separate clock-embedded signals. In this case, the test apparatus 10 receives one of the clock-embedded signals as the data signal, and receives the other as the clock signal.

The test apparatus 10 includes a receiving apparatus 20, a judging section 22, and a control section 24. The receiving apparatus 20 receives the data signal and the clock signal output from the device under test 300.

The receiving apparatus 20 receives the clock-embedded signal from the device under test 300. The receiving apparatus 20 acquires a reception signal received from the device under test 300, using a recovered clock that is recovered from the edge of the reception signal.

The judging section 22 judges pass/fail of the device under test 300 based on the results of the data signal acquisition by the receiving apparatus 20. The control section 24 controls the operation of the receiving apparatus 20 and the judging section 22.

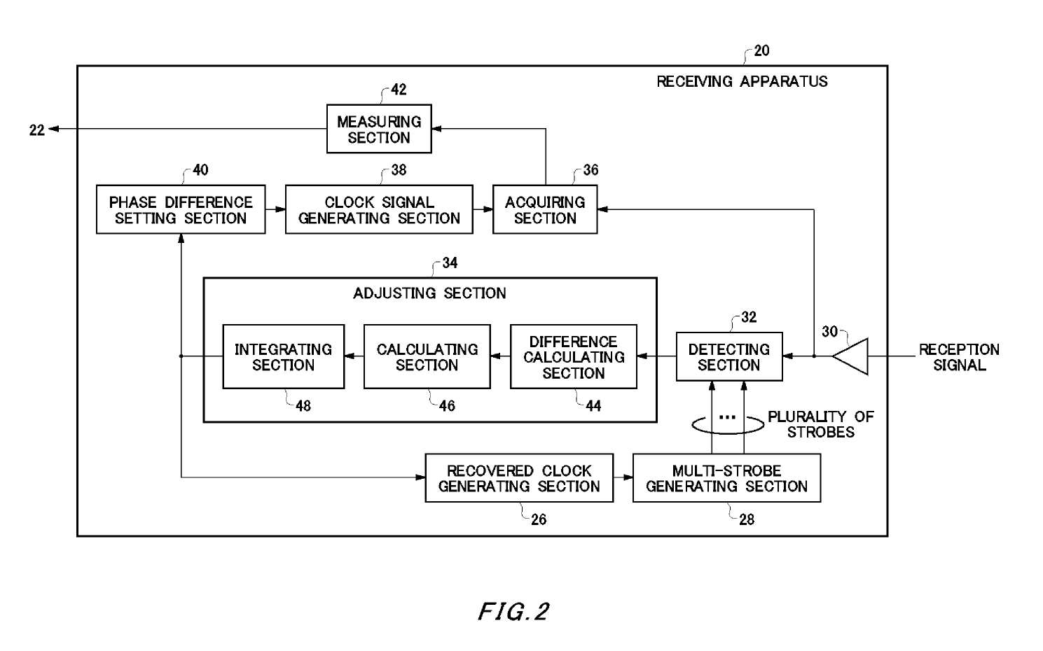

FIG. 2 shows an exemplary configuration within the receiving apparatus 20 according to the present embodiment. The receiving apparatus 20 includes a recovered clock generating section 26, a multi-strobe generating section 28, a first comparator 30, a detecting section 32, an adjusting section 34, an acquiring section 36, a clock signal generating section 38, a phase difference setting section 40, and a measuring section 42.

The recovered clock generating section 26 generates the recovered clock of the reception signal. The recovered clock generating section 26 changes the phase of the recovered clock according to a control amount supplied from the adjusting section 34.

The multi-strobe generating section 28 generates a plurality of strobes at slightly different phases, according to the pulses of the recovered clock. For example, the multi-strobe generating section 28 may generate strobes that are sequentially delayed by prescribed intervals from a reference phase in the recovered clock.

The first comparator 30 compares the level of the reception signal received from the outside to a threshold level, and outputs a signal representing a logic value. The detecting section 32 acquires the value of the reception signal output from the first comparator 30, at the timings of the strobes generated by the multi-strobe generating section 28.

The detecting section 32 detects the edge position of the reception signal relative to the strobes, based on the value of the reception signal at each strobe timing. In other words, the detecting section 32 determines which strobe is used to detect the edge position of the reception signal based on a change in the value of the reception signal in time sequence. The change point of the value of the reception signal may be a rising edge at which the value changes from 0 to 1 or a falling edge at which the value changes from 1 to 0. The detecting section 32 outputs, to the adjusting section 34, the position of the strobe that detected the edge position of the reception signal.

The adjusting section 34 adjusts the phase of the recovered clock according to the edge position of the reception signal. More specifically, the adjusting section 34 adjusts the phase of the recovered clock by supplying the recovered clock generating section 26 with a control amount, and adjusts the position of a predetermined boundary strobe from among the plurality of strobes to match the edge position of the clock signal.

The position of the boundary strobe may be the position of one of the plurality of strobes, or may be a position between two adjacent strobes among the plurality of strobes. The position of the boundary strobe can be changed from the outside, for example.

The adjusting section 34 adjusts the phase of the recovered clock according to the edge position of the reception signal. For example, the adjusting section 34 may include a difference calculating section 44, a calculating section 46, and an integrating section 48. The difference calculating section 44 detects difference data indicating the difference between the position of the boundary strobe and the position of the strobes used to detect the edge position of the reception signal, and code that indicates the before and after relationship between the edge position of the reception signal and the position of the boundary strobe.

When the position of the boundary strobe is earlier than the edge position of the reception signal, the difference calculating section 44 outputs code indicating EARLY. When the position of a first boundary strobe is later than the edge position of the clock signal, the difference calculating section 44 outputs code indicating LATE.

The calculating section 46 generates a control amount for adjusting the phase of the recovered clock, for each cycle, based on the code and first difference data detected by the difference calculating section 44. The integrating section 48 integrates the control amount and supplies the recovered clock generating section 26 with the result. For example, the integrating section 48 may perform low-pass filtering on the control amount output in each cycle, and supply the recovered clock generating section 26 with the result.

In the manner described above, the adjusting section 34 adjusts the phase of the recovered clock for each cycle that includes a single period of the recovered clock or a prescribed number of periods of the recovered clock. As a result, the recovered clock generating section 26 can generate the recovered clock to be phase locked with respect to the reception signal, e.g. to be in synchronization with the phase of the edge position of the reception signal.

The acquiring section 36 acquires the reception signal at a timing that has a set phase difference, which is set in advance, relative to the recovered clock. Since the recovered clock is synchronized with the phase of the edge position of the reception signal, the acquiring section 36 can acquire the signal component at a timing that is phase-shifted by a desired amount from the edge position of the reception signal.

The clock signal generating section 38 generates the clock signal to have a set phase difference, which is set in advance, relative to the recovered clock. The acquiring section 36 acquires the reception signal according to the clock generated by the clock signal generating section 38.

The phase difference setting section 40 sets a plurality of different phase differences as the set phase difference. The acquiring section 36 acquires the reception signal at timings that are respectively shifted from the recovered clock by the plurality of phase differences set by the phase difference setting section 40.

The measuring section 42 measures the value of the reception signal acquired by the acquiring section for each phase difference set as the set phase difference. In other words, the measuring section 42 acquires the value of the reception signal at the timings that are respectively shifted from the recovered clock by the plurality of phase differences set by the phase difference setting section 40. At this time, the recovered clock generating section 26 is generating the recovered clock in synchronization with the phase of the edge position of the reception signal, and therefore the measuring section 42 can measure the value of the reception signal at the timings respectively shifted from the edge position of the reception signal by the phase differences. By obtaining measurement data corresponding to each of the phase differences, the measuring section 42 can acquire a shmoo waveform of the data signal corresponding to each phase.

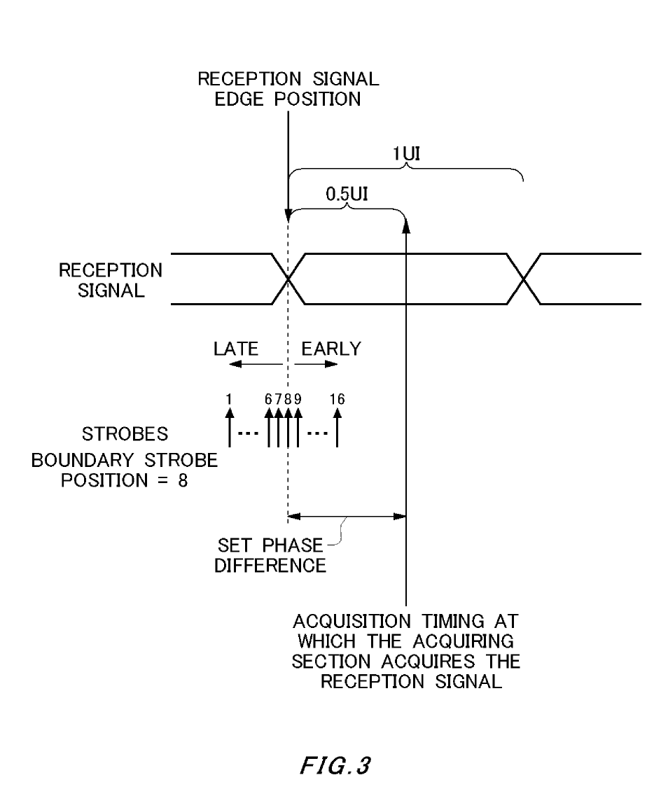

FIG. 3 shows an exemplary process performed by the adjusting section 34 and acquisition timing of the acquiring section 36 according to the present embodiment. The adjusting section 34 shifts the phase of the recovered clock according to the difference between the position of the strobe that detected the edge position of the reception signal and the boundary strobe. In this case, the adjusting section 34 shifts the phase of the recovered clock such that the position of the boundary strobe becomes closer to the edge position of the reception signal.

For example, when the position of the boundary strobe is earlier than the edge position of the reception signal, i.e. when code indicating EARLY is detected, the adjusting section 34 shifts the phase of the recovered clock such that the phase of the recovered clock is delayed by an amount of time corresponding to the difference between the position of the boundary strobe and the position of the strobe that detected the edge position of the reception signal. When the position of the boundary strobe is later than the edge position of the reception signal, i.e. when code indicating LATE is detected, the adjusting section 34 shifts the phase of the recovered clock such that the phase of the recovered clock is made earlier by an amount of time corresponding to the difference between the position of the boundary strobe and the position of the strobe that detected the edge position of the reception signal.

By performing such a process for each cycle, the adjusting section 34 can adjust the phase of the recovered clock such that the position of the boundary strobe, from among the plurality of strobes, moves to be near the edge position of the clock signal. As a result, the adjusting section 34 can synchronize the position of the boundary strobe with the edge position of the reception signal.

In FIG. 3, the plurality of strobes are formed by 16 strobes, which are generated in synchronization with the recovered clock. Here, the eighth strobe is the boundary strobe. The adjusting section 34 matches the position of the eighth strobe to the edge position of the reception signal. The acquiring section 36 acquires the reception signal at a timing that is shifted by the set phase amount, which is set in advance, relative to the recovered clock. Here, the set phase difference is 0.5 UI (unit interval), which is half of the period between two clocks of the reception signal, i.e. half of 1 UI.

The phase of the reception signal is skewed by jitter, wander, and drift, for example. The acquiring section 36 acquires data at a position shifted by 0.5 UI from an edge, i.e. an intermediate point between change points, and can therefore acquire the correct data even when the edge position is skewed when receiving the reception signal.

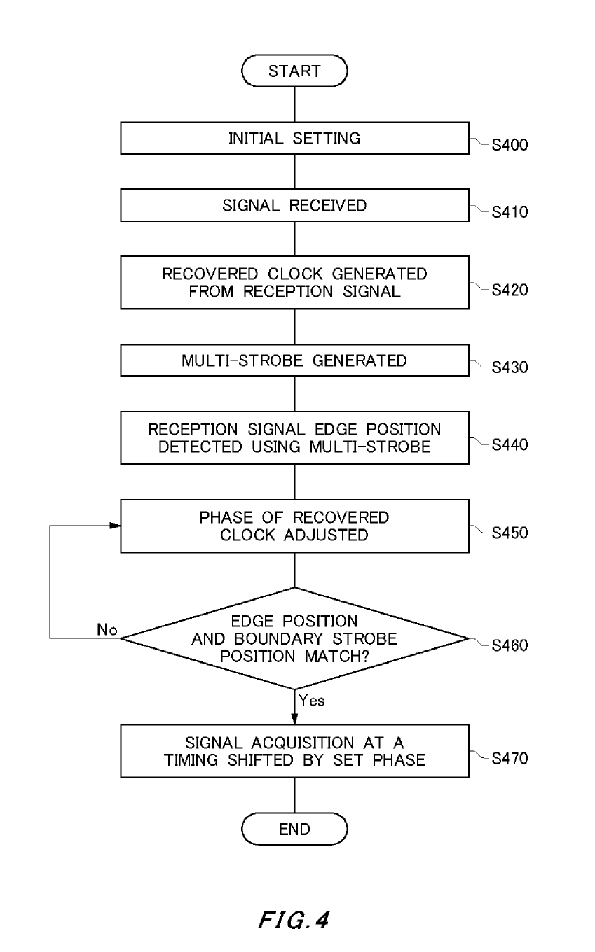

FIG. 4 shows a process flow of the receiving apparatus 20 according to the present embodiment. The receiving apparatus 20 makes an initial setting to be used for data acquisition (S400). The initial setting may include a set phase difference that indicates the acquisition timing of the acquiring section 36 and/or a boundary strobe position, for example.

The receiving apparatus 20 receives a signal (S410). The first comparator 30 compares the level of the reception signal to a threshold level, and outputs a signal indicating a logic value.

The recovered clock generating section 26 generates the recovered clock of the reception signal (S420). When signal reception is begun, the timing at which the recovered clock is generated may be the same as the timing at which the signal is received, or may be a predetermined timing.

The multi-strobe generating section 28 generates the strobes having different phases, according to the pulses of the recovered clock (S430). For example, the multi-strobe generating section 28 may generate strobes that are respectively delayed by prescribed intervals from a reference phase in the recovered clock. The detecting section 32 acquires the value of the reception signal output from the first comparator 30 at the timing of each of the strobes generated by the multi-strobe generating section 28.

The detecting section 32 detects the edge position of the reception signal relative to the strobes, based on the value of the reception signal at each of the strobe timings (S440). The detecting section 32 outputs, to the adjusting section 34, the position of the strobe that detected the edge position of the reception signal.

The adjusting section 34 adjusts the phase of the recovered clock according to the edge position of the reception signal (S450). The adjusting section 34 delays the phase of the recovered clock when the position of the boundary strobe is earlier than the edge position of the reception signal, and causes the phase of the recovered clock to be earlier when the position of the boundary strobe is later than the edge position of the reception signal.

The multi-strobe generating section 28 generates the plurality of strobes according to the adjusted recovered clock. The detecting section 32 detects the edge position of the reception signal relative to the strobes, and checks whether the edge position and the boundary strobe position match or are at a desired interval from each other (S460). If the result of this check is “No,” the process returns to S450. If the result of this check is “Yes,” the process proceeds to S470.

The acquiring section 36 acquires the reception signal at a timing that is shifted by the set phase amount, which is set in advance, from the recovered clock (S470). At this time, if a plurality of phase differences are set by the phase difference setting section 40 as the set phase difference, the acquiring section 36 acquires the reception signal according to each of the phase differences. The measuring section 42 measures the value of the acquired reception signal.

The receiving apparatus 20 described above can measure the data of the reception signal in accordance with the timing of the edge of the reception signal. Furthermore, the test apparatus 10 can test the device under test 300 by using the judging section 22 to judge pass/fail of the device under test 300 based on the results of this data signal acquisition.

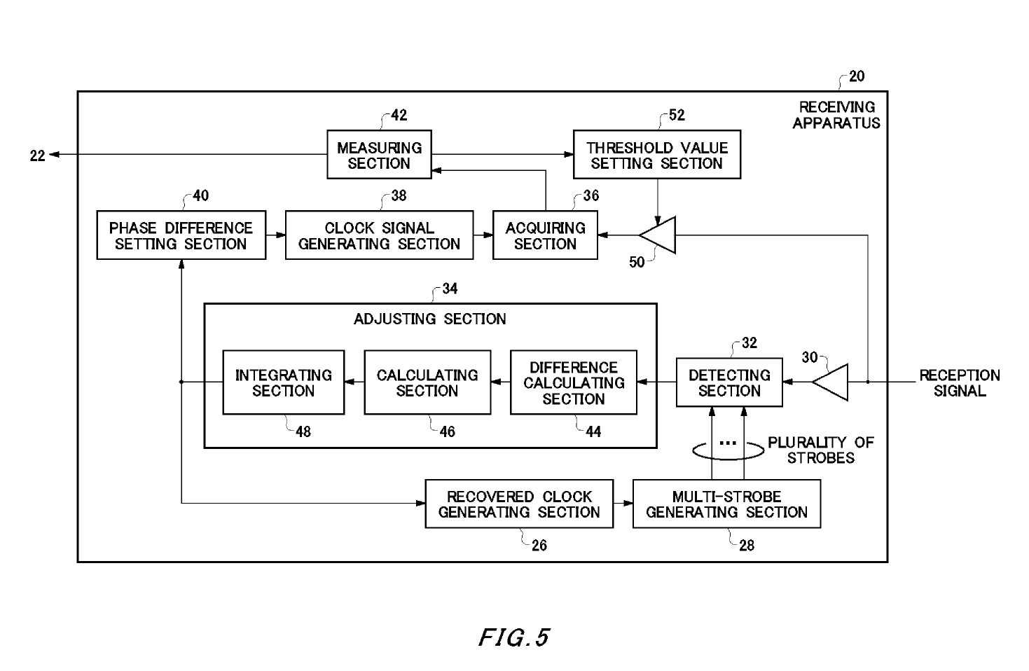

FIG. 5 shows a configuration of the receiving apparatus 20 according to a modification of the present embodiment. The receiving apparatus 20 of the present modification adopts substantially the same function and configuration as the receiving apparatus 20 shown in FIG. 2, and therefore components that have substantially the same function and configuration as those in the receiving apparatus 20 shown in FIG. 2 are given the same reference numerals, and the following description includes only differing points.

The receiving apparatus 20 of the present modification further includes a second comparator 50 that outputs a logic value of the reception signal, and a threshold value setting section 52. The threshold value setting section 52 sets the threshold value to be used by the second comparator 50 to determine the logic value of the reception signal.

The detecting section 32 detects the edge position of the reception signal based on the logic value of the reception signal received from the first comparator 30. The acquiring section 36 acquires the logic value of the reception signal received from the second comparator at a timing that is shifted by the set phase difference relative to the recovered clock. Using the first comparator 30, the receiving apparatus 20 can correctly acquire the edge of the reception signal and generate the recovered clock with the appropriate phase without setting a threshold value for the second comparator.

The measuring section 42 may measure the value of the reception signal acquired by the acquiring section 36 when each of a plurality of threshold values are set in the second comparator 50. The measuring section 42 can acquire the shmoo waveform of the data signal corresponding to each phase and each level of the data signal, by acquiring the measurement data corresponding to each phase difference and each threshold level.

The above embodiments describe an exemplary method for acquiring the data of a reception signal, which includes the acquiring section 36 acquiring the reception signal at a timing that is shifted by the set phase amount, which is set in advance, relative to the recovered clock. Here, the acquiring section 36 may acquire the reception signal at a timing of a predetermined acquisition strobe from among the plurality of strobes. The acquiring section 36 can acquire the reception signal at a timing that is shifted from the edge of the reception signal by an amount equal to the phase difference between the boundary strobe and the acquisition strobe.

The acquiring section 36 may acquire the reception signal at the timing of the acquisition strobe corresponding to a position shifted by half a period of the reception signal from the position of the boundary strobe. In this way, the acquiring section 36 can acquire data at a position shifted from the boundary strobe by 0.5 UI or a value near 0.5 UI.

The above embodiments describe examples in which the reception signal is transmitted on one transmission line, but instead, the reception signal may be transmitted on two transmission lines by being divided into the data signal and the clock signal of a clock-embedded signal. In this case, the detecting section 32 preferably receives the clock signal via the first comparator 30, and the acquiring section 36 preferably acquires the data signal via the second comparator 50.

The above embodiments describe an example in which the test apparatus tests a device that outputs a data signal in parallel with a clock signal indicating the acquisition timing of this data signal or a device that outputs a signal obtained by superimposing a clock component on a data signal. However, the embodiments of the present invention are not limited to a test apparatus, and may include a receiving apparatus that receives a signal from the devices described above, using a multi-strobe.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A receiving apparatus that acquires a reception signal using a recovered clock that is recovered from an edge of the reception signal, the receiving apparatus comprising:
a recovered clock generating section that generates the recovered clock;
a multi-strobe generating section that generates a plurality of strobes having different phases from each other, according to a pulse of the recovered clock;
a detecting section that detects an edge position of the reception signal relative to the strobes, based on a value of the reception signal at timings of each of the strobes;
an adjusting section that adjusts a phase of the recovered clock according to the edge position of the reception signal; and
an acquiring section that acquires the reception signal at a timing shifted by a set phase difference, which is set in advance, from the recovered clock.

2. The receiving apparatus according to claim 1, further comprising a clock signal generating section that generates a clock signal shifted by the set phase difference from the recovered clock, wherein
the acquiring section acquires the reception signal at a timing of the clock signal.

3. The receiving apparatus according to claim 1, further comprising:
a phase difference setting section that sets each of a plurality of phase differences as the set phase difference; and
a measuring section that measures a value of the reception signal acquired by the acquiring section for each of the phase differences set as the set phase difference.

4. The receiving apparatus according to claim 3, further comprising a first comparator and a second comparator that each receive the reception signal and output a logic value of the reception signal, wherein
the detecting section detects the edge position of the reception signal based on the logic value of the reception signal received from the first comparator, and
the acquiring section acquires the logic value of the reception signal received from the second comparator, at a timing that is shifted by the set phase difference from the recovered clock.

5. The receiving apparatus according to claim 4, further comprising a threshold value setting section that sets a threshold value used by the second comparator to determine the logic value of the reception signal, wherein
the measuring section measures the value of reception signal acquired by the acquiring section for each of the threshold values set in the second comparator.

6. The receiving apparatus according to claim 1, wherein
the acquiring section acquires the reception signal at a timing of a predetermined acquisition strobe from among the plurality of strobes.

7. The receiving apparatus according to claim 6, wherein
the adjusting section adjusts the position of a predetermined boundary strobe from among the plurality of strobes to match the edge position of the reception signal, by adjusting the phase of the recovered clock, and
the acquiring section acquires the reception signal at the timing of the acquisition strobe corresponding to a position that is shifted by half a period of the reception signal from a position of the boundary strobe.

8. A test apparatus that tests a device under test, comprising:
the receiving apparatus according to claim 1; and
a judging section that judges pass/fail of the device under test based on a result of the reception signal acquisition by the receiving apparatus.

9. A receiving method for acquiring a reception signal using a recovered clock that is recovered from an edge of the reception signal, the receiving method comprising:
generating the recovered clock;
generating a plurality of strobes having different phases from each other, according to a pulse of the recovered clock;
detecting an edge position of the reception signal relative to the strobes, based on a value of the reception signal at timings of each of the strobes;
adjusting a phase of the recovered clock according to the edge position of the reception signal; and
acquiring the reception signal at a timing shifted by a set phase difference, which is set in advance, from the recovered clock.

10. A test method for testing a device under test with a test apparatus, the test method comprising:
judging pass/fail of the device under test using the test apparatus, based on a result of the acquisition of the reception signal received using the receiving method according to claim 9.
